(19) United States
(12) Patent Application Publication
(10) Pub. No.: US 2026/0190774 A1
(43) Pub. Date: Jul. 2, 2026

(54) DISPLAY DEVICE

(71) Applicant: LG Display Co., Ltd., Seoul (KR)

(72) Inventor: DongHun JUNG, Paju-si (KR)

(73) Assignee: LG Display Co., Ltd., Seoul (KR)

(21) Appl. No.: 19/222,650

(22) Filed: May 29, 2025

(30) Foreign Application Priority Data
Dec. 31, 2024 (KR) 10-2024-0202715

(51) Int. Cl. H10K 59/80; G06F 3/041

(52) U.S. Cl. CPC H10K 59/873; G06F 3/0412

(57) ABSTRACT

A display device in some aspects includes a substrate having a display area and a non-display area surrounding the display area, a plurality of dams on the substrate so as to surround the display area in the non-display area, a plurality of hanging units on the substrate at an outer periphery of the non-display area and disposed further than the plurality of dams, and a planarization layer in the display area and the non-display area. The planarization layer fills areas between the plurality of dams and between the plurality of hanging units in the non-display area.

### CROSS-REFERENCE TO RELATED APPLICATIONS

This application claims priority to Korean Patent Application No. 10-2024-0202715 filed on Dec. 31, 2024, in the Korean Intellectual Property Office, the disclosure of which is hereby expressly incorporated by reference into the present application.

### BACKGROUND

### Field

The present disclosure relates to a display device, and more particularly, to a display device which minimizes or prevents generation and propagation of cracks at an outer periphery of a display panel.

### Description of the Related Art

As the world enters the information era, a field of a display device which visually expresses electrical information signals has been rapidly developed and studies continue to improve performances of various display devices, such as a thin-thickness, a light weight, and low power consumption.

A representative display device can include a liquid crystal display (LCD) device, a field emission display (FED) device, an electro-wetting display (EWD) device, and an organic light emitting display (OLED) device.

An electroluminescent display device which is represented by an organic light emitting display device is a self-emitting display device so that a separate light source is not necessary, which is different from a liquid crystal display device. Therefore, the electroluminescent display device can be manufactured to have a light weight and a small thickness. Further, since the electroluminescent display device is advantageous not only in terms of power consumption due to the low voltage driving, but also in terms of color implementation, a response speed, a viewing angle, and a contrast ratio (CR), it is expected to be utilized in various fields.

### SUMMARY OF THE DISCLOSURE

An object to be achieved by the present disclosure is to provide a display device which minimizes separation of an interface of the substrate and an organic layer at the outermost periphery of the display panel.

Another object to be achieved by the present disclosure is to provide a display device which minimizes or prevents a crack from being transmitted to a display area even when a crack may be generated at the outer periphery of the display panel.

Still another object to be achieved by the present disclosure is to provide a low-power display device which minimizes or prevents generation and propagation of a crack at the outer periphery of the display panel to improve the reliability of the display device, thereby improving a lifespan to reduce power consumption.

Objects of the present disclosure are not limited to the above-mentioned objects, and other objects, which are not mentioned above, can be clearly understood by those skilled in the art from the following descriptions.

According to aspects of the present disclosure, a display device includes a substrate including a display area and a non-display area surrounding the display area, a plurality of dams on the substrate so as to surround the display area in the non-display area, a plurality of hanging units on the substrate at an outer periphery of the non-display area more than the plurality of dams, and a planarization layer in the display area and the non-display area and filling between the plurality of dams and between the plurality of hanging units in the non-display area.

According to aspects of the present disclosure, a display device includes a substrate including a display area and a non-display area surrounding the display area, a plurality of hanging units on the substrate at an outer periphery of the non-display area, and a planarization layer in the display area and the non-display area in which the substrate includes a plurality of grooves between the plurality of hanging units and the planarization layer fills the plurality of grooves in the non-display area.

Other detailed matters of the example embodiments of the present disclosure are included in the detailed description and the drawings.

According to aspects of the present disclosure, in the display device, a crack of an inorganic material which may be generated in a trimming line is minimized while minimizing separation of an interface of the substrate and the organic layer at the outermost periphery of the display panel to improve the reliability of the display device.

According to aspects of the present disclosure, in the display device, propagation of the crack which may be generated at the outer periphery of the display panel to the display area is minimized to improve the display quality of the display device.

According to aspects of the present disclosure, in the display device, generation and propagation of the crack at the outer periphery of the display panel are minimized to improve reliability and a lifespan of the display device, thereby implementing a low-power display device with reduced power consumption.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to one or more example embodiments of the present disclosure;

FIG. 2 is a cross-sectional view taken along line II-II′ of FIG. 1;

FIG. 3 is a cross-sectional view taken along line III-III′ of FIG. 1;

FIG. 4 is an enlarged cross-sectional view of an area F of FIG. 3;

FIG. 5 is a cross-sectional view of a display device according to another example embodiment of the present disclosure;

FIGS. 6A to 6D are process disagrams for explaining a manufacturing method of a display device according to another example embodiment of the present disclosure; and

FIG. 7 is a schematic plan view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” fully encompasses all the meanings and coverages of the term “may” and vice versa.

Hereinafter, various embodiments of the present disclosure will be described in detail with reference to accompanying drawings. All the components of each display device according to all embodiments of the present disclosure are operatively coupled and configured.

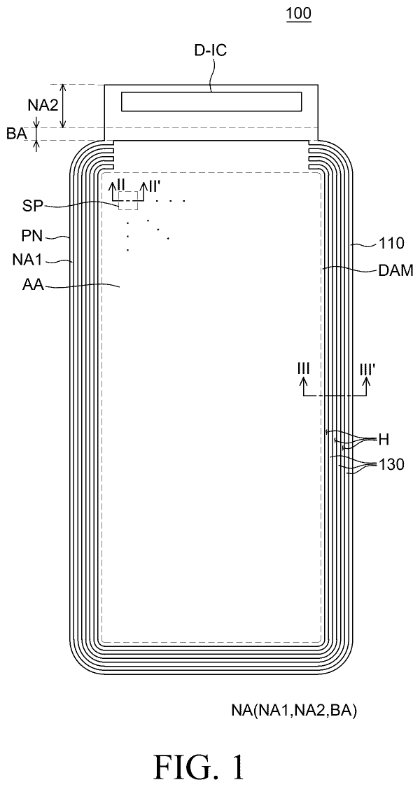

FIG. 1 is a schematic plan view of a display device according to one or more example embodiments of the present disclosure. In FIG. 1, among various components of a display device 100, a display panel PN, a driving integrated circuit (IC) D-IC, a dam DAM, and a plurality of hanging units 130 are illustrated.

Referring to FIG. 1, the display device 100 according to aspects of the present disclosure includes a driving IC D-IC, the dam DAM, and the plurality of hanging units 130 on the display panel PN.

The display panel PN is a panel for displaying images to a user. In the display panel PN, a light emitting diode which displays images, a driving element which drives the light emitting diode, and wiring lines which transmit various signals to the light emitting diode and the driving element can be disposed. Therefore, the display panel PN can include a substrate 110 for supporting various components of the display device 100.

The light emitting diode can be defined in different manners depending on the type of the display panel PN. For example, when the display panel PN is an organic light emitting display panel PN, the light emitting diode can be an organic light emitting diode which includes an anode, an organic emission layer, and a cathode. For example, when the display panel PN is a liquid crystal display panel, the light emitting diode can be a liquid crystal display element. Hereinafter, even though the display panel PN is assumed as an organic light emitting display panel, the display panel PN is not limited to the organic light emitting display panel.

The display panel PN includes a display area AA (or active area) and a non-display area NA (or non-active area). The non-display area NA can surround the display area AA entirely or only in part(s).

The display area AA is an area where images are displayed in the display panel PN. In the display area AA, a plurality of sub pixels SP which configures a plurality of pixels and a driving circuit for driving the plurality of sub pixels SP can be disposed.

The plurality of sub pixels SP is minimum units which configure the display area AA and a light emitting diode can be disposed in each of the plurality of sub pixels SP. For example, an organic light emitting diode which includes an anode, an organic emission layer, and a cathode can be disposed in each of the plurality of sub pixels SP, but it is not limited thereto. Further, the driving circuit for driving the plurality of sub pixels SP can include a driving element and a wiring line. For example, the driving circuit can be configured by a thin film transistor, a storage capacitor, a gate line, and a data line, but is not limited thereto.

The non-display area NA is an area where no image is displayed. The non-display area NA can refer to an outer peripheral portion of the display panel PN, which surrounds the display area AA. The non-display area NA can overlap a black matrix. In the non-display area NA, various wiring lines and circuits for driving the organic light emitting diode of the display area AA are disposed. For example, in the non-display area NA, a link line which transmits signals to the plurality of sub pixels SP and driving circuits of the display area AA or a driving IC D-IC such as a gate driver IC or a data driver IC can be disposed, but it is not limited thereto.

The non-display area NA includes a first non-display area NA1, a bending area BA, and a second non-display area NA2.

The first non-display area NA1 is an area which surrounds the display area AA and extends from the display area AA. The bending area BA can extend from one side of the first non-display area NA1 and can be bent. The second non-display area NA2 is an area which extends from the bending area BA to be disposed on the display area AA.

The first non-display area NA1 and the second non-display area NA2 are disposed on the same plane as the display area AA or disposed to be parallel to the display area AA and maintain a flat state. For example, the first non-display area NA1 can be disposed to be flat on the same plane as the display area AA and the second non-display area NA2 can be disposed on the display area AA to be parallel to the display area AA and be flat. Therefore, the display area AA, the first non-display area NA1, and the second non-display area NA2 can be referred to as non-bending areas, but are not limited thereto.

A dam DAM and a plurality of hanging units 130 are disposed on the substrate 110 at the outside of the first non-display area NA1.

The dam DAM can be disposed so as to surround the display area AA.

The plurality of hanging units 130 can be disposed so as to surround the dam DAM. The plurality of hanging units 130 can be disposed to be close to a trimming line. For example, the plurality of hanging units 130 can be disposed along trimming lines at a left side, a right side, and a lower side of the display panel PN. The plurality of hanging units 130 can be configured to increase adhesion of an organic layer disposed above the substrate 110 and the substrate 110 and perform a hanging function. In the meantime, the plurality of hanging units 130 can include at least one inorganic layer.

At this time, the plurality of hanging units 130 can have a linear shape along an outline of the display panel PN. For example, the plurality of linear hanging units 130 can be disposed so as to be parallel to the dam DAM. Therefore, the plurality of hanging units 130 can minimize the separation of the interface of the organic layer and the substrate 110 at the outer periphery of the first non-display area NA1.

In the meantime, even though in FIG. 1, it is illustrated that the plurality of hanging units 130 is three, a bezel size of the display panel PN can be adjusted according to the number of the plurality of hanging units 130 so that the present disclosure is not limited thereto.

The substrate 110 includes a plurality of grooves H between the dam DAM and the plurality of hanging units 130 and between the plurality of hanging units 130, at the outer periphery of the first non-display area NA1. At this time, an end portion of the inorganic layer which is disposed so as to cover the dam DAM can be exposed by the plurality of grooves H. Therefore, the plurality of hanging units 130 is disconnected from the inorganic layer which is disposed so as to cover the dam DAM, by the plurality of grooves H, so that the crack of the inorganic layer which can propagate to the substrate 110 can be minimized.

In the second non-display area NA2, a driving IC D-IC is disposed. The driving IC D-IC can supply a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. The driving IC D-IC supplies a data signal through the plurality of data lines. For example, in the second non-display area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel PN in a chip on panel (COP) manner to be connected to the display panel PN or is disposed in a separate flexible film to be connected to the display panel PN in a chip on film (COF) manner. In the display device 100 according to the example embodiment of the present disclosure, it is assumed that the driving IC D-IC is disposed in the COP manner, but it is not limited thereto.

As the display panel PN is bent, the driving IC D-IC disposed in the non-display area NA2 can be disposed below the display area AA. For example, the driving IC D-IC and the printed circuit board connected to the pad unit of the display panel PN can move to the rear surface of the display panel PN and overlap the display area AA. Therefore, as seen from the top of the display panel PN, circuit elements, such as the driving IC D-IC and the printed circuit board may not be visible. Accordingly, a size of the non-display area NA which is visible from the top of the display panel PN is reduced to implement a narrow bezel.

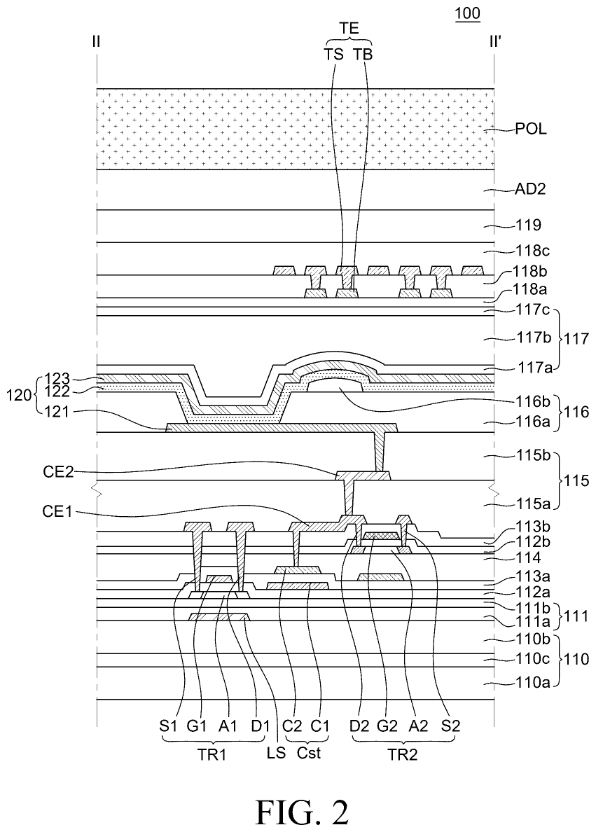

Hereinafter, a cross-sectional structure of the display area AA of the display device 100 will be described in more detail with reference to FIG. 2 together. FIG. 2 is a cross-sectional view taken along line II-II′ of FIG. 1. FIG. 2 is a cross-sectional view of one sub pixel SP disposed in a display area AA according to an example embodiment of the present disclosure.

Referring to FIG. 2, in the display device 100 according to the example embodiment of the present disclosure, in the display area AA of the display panel PN, a substrate 110, a light shielding layer LS, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a first connection electrode CE1, a first planarization layer 115a, a second planarization layer 115b, a second connection electrode CE2, a bank 116a, a spacer 116b, a light emitting diode 120, an encapsulation unit 117, a touch buffer layer 118a, a touch sensing layer, a touch interlayer insulating layer 118b, a touch planarization layer 118c, a third planarization layer 119, a second adhesive layer AD2, and a polarizer POL are disposed.

The substrate 110 serves to support and protect components of the display device 100 disposed thereabove.

The substrate 110 is a component for supporting various components included in the display device 100 and can be formed of an insulating material. In the meantime, the substrate 110 is disposed so as to support components on the lowermost portion of the display device 100 so that the substrate can also be referred to as a lower substrate, but is not limited thereto.

The substrate 110 can include a first substrate 110a, a second substrate 110b, and an insulating film 110c. The insulating film 110c can be disposed between the first substrate 110a and the second substrate 110b. As described above, the substrate 110 is configured by the first substrate 110a, the second substrate 110b, and the insulating film 110c to suppress the moisture permeation. However, the substrate 110 can be disposed as a single layer, but is not limited thereto.

For example, the first substrate 110a and the second substrate 110b can be polyimide (PI) substrates and the interlayer insulating film 110c can be formed of a single layer of silicon nitride (SiNx) or silicon oxide (SiOx) or multiple layers thereof.

The insulating film 110c may not be disposed in at least a part area. For example, the insulating film 110c may not be formed in an area to which a stress is concentrated, such as a bending area BA or an outermost area.

The light shielding layer LS can be disposed on the substrate 110. The light shielding layer LS is a protection layer formed of metal which is disposed below semiconductor layers A1 and A2 of a plurality of transistors TR1 and TR2 to shield external light. The light shielding layer LS can minimize damage of the semiconductor layers A1 and A2 which is caused by the external light.

The first buffer layer 111 can be disposed on the substrate 110 while covering the light shielding layer LS. Specifically, a multi-buffer layer 111a can be disposed on the substrate 110 while covering the light shielding layer LS and an active buffer layer 111b can be disposed on the multi-buffer layer 111a.

The multi-buffer layer 111a can delay diffusion of the moisture or oxygen permeating the substrate 110 and include at least any one of silicon nitride (SiNx) and silicon oxide (SiOx).

The active buffer layer 111b can protect the first semiconductor layer A1 and block various types of defects introduced from the substrate 110. For example, the active buffer layer 111b can include at least any one of amorous silicon (a-Si), silicon nitride (SiNx), and silicon oxide (SiOx).

The first thin film transistor TR1 can be disposed on the first buffer layer 111. The first thin film transistor TR1 can include the first semiconductor layer A1, a first gate electrode G1, a first source electrode S1, and a first drain electrode D1. Here, depending on the design of the pixel circuit, the first source electrode S1 can serve as a first drain electrode and the first drain electrode D1 can serve as a first source electrode.

The first semiconductor layer A1 can be disposed on the first buffer layer 111 so as to overlap the light shielding layer LS. The first semiconductor layer A1 can include amorphous silicon or polycrystalline silicon. For example, the first semiconductor layer A1 can include a low-temperature polycrystalline silicon LTPS. For example, the polycrystalline silicon material has a high mobility (100 cm²/Vs or higher) so that energy power consumption is low and reliability is excellent. Therefore, the polycrystalline silicon material can be applied to a gate driver for driving elements which drive thin film transistors for a light emitting diode and/or a multiplexer (MUX) and also applied as a first semiconductor layer A1 of a driving thin film transistor of the display device 100 according to the example embodiment, but is not limited thereto. For example, the polycrystalline silicon material can also be applied as a second semiconductor layer A2 of the switching thin film transistor according to the characteristic of the display device 100. An amorphous silicon (a-Si) material is deposited on the first buffer layer 111 and a dehydrogenation process and a crystallization process are performed to form polycrystalline silicon and the polycrystalline silicon is patterned to form the first semiconductor layer A1.

Here, the first semiconductor layer A1 can include a first channel region in which a channel is formed when the first thin film transistor T1 is driven and a first source region and a first drain region on both sides of the first channel region. The first source region refers to a part of the first semiconductor layer A1 which is connected to the first source electrode S1 and the first drain region refers to a part of the first semiconductor layer A1 which is connected to the first drain electrode D1. For example, the first source region and the first drain region can be configured by ion-doping (impurity doping) of the first semiconductor layer A1. The first source region and the first drain region can be generated by doping ions into the polycrystalline silicon material and the first channel region can refer to a part in which the ions are not doped, but the polycrystalline silicon material remains.

The first gate insulating layer 112a can be disposed on the first semiconductor layer A1. The first gate insulating layer 112a can be configured by a single layer of silicon nitride (SiNx) or silicon oxide (SiOx) or multiple layers thereof. In the first gate insulating layer 112a, a contact hole through which the first source electrode S1 and the first drain electrode D1 of the first thin film transistor TR1 are connected to the first source region and the first drain region of the first semiconductor layer A1 of the first thin film transistor TR1, respectively, can be formed.

The first gate electrode G1 of the first thin film transistor TR1 and a first capacitor electrode C1 of the storage capacitor Cst can be disposed on the first gate insulating layer 112a.

At this time, the first gate electrode G1 and the first capacitor electrode C1 can be formed by a single layer or multiple layers formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 can be formed on the first gate insulating layer 112a so as to overlap the first channel region of the first semiconductor layer A1 of the first thin film transistor TR1.

The first capacitor electrode C1 can be omitted based on a driving characteristic of the display device 100 and a structure and a type of the thin film transistor. The first gate electrode G1 and the first capacitor electrode C1 can be formed by the same process. Further, the first gate electrode G1 and the first capacitor electrode C1 can be formed of the same material on the same layer.

The first interlayer insulating layer 113a can be disposed above the first gate insulating layer 112a, the first gate electrode G1, and the first capacitor electrode C1. The first interlayer insulating layer 113a can be configured by a single layer of silicon nitride (SiNx) or silicon oxide (SiOx) or multiple layers thereof. In the first interlayer insulating layer 113a, a contact hole for exposing the first source region and the first drain region of the first semiconductor layer A1 of the first thin film transistor TR1 can be formed.

A second capacitor electrode C2 of the storage capacitor Cst can be disposed on the first interlayer insulating layer 113a. The second capacitor electrode C2 can be formed by a single layer or multiple layers formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 can be formed on the first interlayer insulating layer 113a so as to overlap the first capacitor electrode C1. Further, the second capacitor electrode C2 can be formed of the same material as the first capacitor electrode C1. The second capacitor electrode C2 can be omitted based on a driving characteristic of the display device 100 and a structure and a type of the thin film transistor.

The second buffer layer 114 can be disposed on the first interlayer insulating layer 113a and the second capacitor electrode C2. The second buffer layer 114 can be configured by a single layer of silicon nitride (SiNx) or silicon oxide (SiOx) or multiple layers thereof. A contact hole for exposing the first source region and the first drain region of the first semiconductor layer A1 of the first thin film transistor TR1 can be formed in the second buffer layer 114. Further, in the second buffer layer 114, a contact hole for exposing the second capacitor electrode C2 of the storage capacitor Cst can be formed.

The second buffer layer 114 can be formed by multiple layers, but is not limited thereto.

The second semiconductor layer A2 of the second thin film transistor TR2 can be disposed on the second buffer layer 114. Here, the second thin film transistor TR2 can include the second semiconductor layer A2, a second gate insulating layer 112b, a second gate electrode G2, a second source electrode S2, and a second drain electrode D2. Here, depending on the design of the pixel circuit, the second source electrode S2 can serve as a drain electrode and the second drain electrode D2 can serve as a source electrode.

Further, the second semiconductor layer A2 can include a second channel region in which a channel is formed when the second thin film transistor TR2 is driven, and a second source region and a second drain region on both sides of the second channel region. The second source region can refer to a part of the second semiconductor layer A2 which is connected to the second source electrode S2 and the second drain region can refer to a part of the second semiconductor layer A2 which is connected to the second drain electrode D2.

The second semiconductor layer A2 can be formed of an oxide semiconductor. The oxide semiconductor material has a larger band gap than a silicon material so that electrons cannot jump over the band gap in an off state. Therefore, the oxide semiconductor material has a low off-current. Therefore, the thin film transistor including a semiconductor layer which is formed of an oxide semiconductor can be suitable for a switching thin film transistor which maintains on-time to be short and off-time to be long, but is not limited thereto.

Depending on the characteristic of the display device 100, a thin film transistor including a semiconductor layer formed of oxide semiconductor can be applied as a driving thin film transistor. Further, due to the small off-current, a magnitude of an auxiliary capacitance can be reduced so that it can be appropriate for a high resolution light emitting diode. For example, the second semiconductor layer A2 can be formed of metal oxide and for example, can be formed of various metal oxide such as indium-gallium-zinc-oxide (IGZO). Here, the description was made under assumption that the second semiconductor layer 2 of the second thin film transistor TR2 is configured by IGZO, among various metal oxides, but it is not limited thereto. Therefore, the second semiconductor layer can be formed of another metal oxide such as indium-zinc-oxide (IZO), indium-gallium-tin-oxide (IGTO), or indium-gallium-oxide (IGO), rather than IGZO.

The second semiconductor layer A2 can be formed by depositing the metal oxide on the second buffer layer 114, performing a heat treatment for stabilization, and then patterning the metal oxide.

The second gate insulating layer 112b can be disposed on the entire substrate 110 including the second semiconductor layer A2. For example, the second gate insulating layer 112b can be configured by a single layer of silicon nitride (SiNx) or silicon oxide (SiOx) or multiple layers thereof.

The second gate electrode G2 can be disposed on the second gate insulating layer 112b.

The second gate electrode G2 can be formed by a single layer or multiple layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material can be used.

The second interlayer insulating layer 113b can be disposed on the second gate insulating layer 112b and the second gate electrode G2. A contact hole for exposing the first semiconductor layer A1 of the first thin film transistor TR1 and the second semiconductor layer A2 of the second thin film transistor TR2 can be formed in the second interlayer insulating layer 113b. For example, a contact hole for exposing the first source region and the first drain region of the first semiconductor layer A1 of the first thin film transistor TR1 can be formed in the second interlayer insulating layer 113b. A contact hole for exposing the second source region and the second drain region of the second semiconductor layer A2 of the second thin film transistor TR2 can be formed in the second interlayer insulating layer 113b.

The second interlayer insulating layer 113b can be configured as a single layer of silicon nitride (SiNx) or silicon oxide (SiOx) or multiple layers thereof.

A first connection electrode CE1, the first source electrode S1 and the first drain electrode D1 of the first thin film transistor T1 and the second source electrode S2 and the second drain electrode D2 of the second thin film transistor T2 can be disposed on the second interlayer insulating layer 113b.

The first connection electrode CE1 can be electrically connected to the second drain electrode D2 of the second thin film transistor TR2. Further, the first connection electrode CE1 can be electrically connected to the second capacitor electrode C2 of the storage capacitor Cst through the contact holes formed in the second buffer layer 114 and the second interlayer insulating layer 113b. For example, the first connection electrode CE1 can serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR1 can be connected to the first semiconductor layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 can be connected to the second semiconductor layer A2 through the contact hole formed in the second interlayer insulating layer 113b.

The first connection electrode CE1, the first source electrode S1 and the first drain electrode D1 of the first thin film transistor TR1 and the second source electrode S2 and the second drain electrode D2 of the second thin film transistor TR2 can be formed of the same material by the same process.

For example, the first connection electrode CE1, the first source electrode S1 and the first drain electrode D1 of the first thin film transistor TR1 and the second source electrode S2 and the second drain electrode D2 of the second thin film transistor TR2 can be formed by a single layer or multiple layers formed of any one of molybdenum (Mo), copper (Cu), titanium (Ti), aluminum (Al), chrome (Cr), gold (Au), nickel (Ni), and neodymium (Nd) or an alloy thereof. For example, the first connection electrode CE1, the first source electrode S1 and the first drain electrode D1 of the first thin film transistor TR1 and the second source electrode S2 and the second drain electrode D2 of the second thin film transistor TR2 can be formed of a triple layered structure of titanium (Ti)/aluminum (Al)/titanium (Ti), but are not limited thereto.

Further, the first connection electrode CE1 can be integrally formed to be connected to the second drain electrode D2 of the second thin film transistor TR2, but is not limited thereto.

The first planarization layer 115a can be disposed above the first connection electrode CE1, the first source electrode S1 and the first drain electrode D1 of the first thin film transistor TR1 and the second source electrode S2 and the second drain electrode D2 of the second thin film transistor TR2, and the second interlayer insulating layer 113b.

The first planarization layer 115a can be an organic layer which planarizes and protects upper portions of the first thin film transistor TR1 and the second thin film transistor TR2. For example, the first planarization layer 115a can be formed of an organic material such as acryl resin, epoxy resin, phenolic resin, polyamide resin, or polyimide resin.

The second connection electrode CE2 can be disposed on the first planarization layer 115a. The second connection electrode CE2 can be connected to the second drain electrode D2 of the second thin film transistor TR2 through the contact hole of the first planarization layer 115a. The second connection electrode CE2 can serve to electrically connect the second thin film transistor TR2 and the anode 121 with each other. The second connection electrode CE2 can be formed by a single layer or multiple layers formed of any one of molybdenum (Mo), copper (Cu), titanium (Ti), aluminum (Al), chrome (Cr), gold (Au), nickel (Ni), and neodymium (Nd) or an alloy thereof. The second connection electrode CE2 can be formed of the same material as the second source electrode S2 and the second drain electrode D2 of the second thin film transistor TR2.

The second planarization layer 115b can be disposed above the second connection electrode CE2 and the first planarization layer 115a. For example, the second planarization layer 115b can be formed of an organic material, such as acryl resin, epoxy resin, phenolic resin, polyamide resin, or polyimide resin.

The light emitting diode 120 can be disposed on the second planarization layer 115b. The light emitting diode 120 includes an anode 121, an emission layer 122, and a cathode 123.

The anode 121 can be disposed on the second planarization layer 115b. At this time, the anode 121 can be electrically connected to the second connection electrode CE2 through the contact hole provided in the second planarization layer 115b. The anode 121 can be formed of a metallic material. The anode 121 can be a first electrode.

When the display device 100 is a top emission type in which light emitted from the light emitting diode 120 is emitted above the substrate 110 on which the light emitting diode 120 is disposed, the anode 121 can include a reflective layer and a transparent conductive layer disposed on the reflective layer. The transparent conductive layer can be formed of transparent conductive oxide such as indium tin oxide (ITO) or indium zinc oxide (IZO) and the reflective layer can be formed of silver (Ag), aluminum (Al), gold (Au), molybdenum (Mo), tungsten (W), chrome (Cr), or an alloy thereof, but they are not limited thereto.

The bank unit 116 can be disposed on the anode 121. The bank unit 116 includes a bank 116a and a spacer 116b.

The bank 116a can be disposed while covering an end of the anode 121. A part of the bank 116a corresponding to an emission area of the sub pixel can be open. A part of the anode 121 can be exposed through the open part of the bank 116a (hereinafter, referred to as an open area). At this time, the bank 116a can be formed of an inorganic insulating material, such as silicon nitride (SiNx) or silicon oxide (SiOx), or an organic insulating material, such as benzocyclobutene resin, acrylic resin or imide resin, but is not limited thereto.

The spacer 116b can be disposed on the bank 116a. The spacer 116b can serve to maintain a predetermined gap so as not to allow a mask to be in contact with a substrate during a manufacturing process of an emission layer 122 of the light emitting diode 120 which is formed of an organic material.

For example, the spacer 116b can be formed of an inorganic insulating material, such as silicon nitride (SiNx) or silicon oxide (SiOx), or an organic insulating material, such as benzocyclobutene resin, acrylic resin or imide resin, but is not limited thereto.

The emission layer 122 is disposed on the anode 121, the bank 116a, and the spacer 116b. The emission layer 122 can be disposed in the open area of the bank 116a and in the vicinity of the open area of the bank. Therefore, the emission layer 122 can be disposed on the anode 121 exposed through the open area of the bank 116a.

The emission layer 122 can include a plurality of organic layers. For example, the emission layer 122 can include an organic layer such as a hole injection layer, a hole transport layer, an electron transport layer, and an electron injection layer. In the meantime, when the emission layer 122 emits white light, light emitted from the emission layer 122 can be converted into light with various colors by a plurality of color filters, but is not limited thereto.

The cathode 123 is disposed on the emission layer 122. The cathode 123 supplies electrons to the emission layer 122 so that the cathode can be formed of a conductive material having a low work function. The cathode 123 can be formed as one layer over the plurality of sub pixels SP. For example, the cathodes 123 of the plurality of sub pixels SP are connected to be integrally formed.

For example, the cathode 123 can be formed of a transparent conductive material such as indium tin oxide (ITO) and indium zinc oxide (IZO) or ytterbium (Yb) alloy and can further include a metal doping layer, but is not limited thereto. The cathode 123 can be a second electrode.

The encapsulation unit 117 is disposed on the light emitting diode 120.

The encapsulation unit 117 can have a single layer structure or a multi-layered structure. For example, the encapsulation unit 117 can have a multi-layered structure including a first encapsulation layer 117a, a second encapsulation layer 117b, and a third encapsulation layer 117c. However, the encapsulation unit can also be formed with a single layer structure, but is not limited thereto.

The first encapsulation layer 117a and the third encapsulation layer 117c can be formed of inorganic materials and the second encapsulation layer 117b can be formed of an organic material. The second encapsulation layer 117b can be the thickest among the first encapsulation layer 117a, the second encapsulation layer 117b, and the third encapsulation layer 117c. The second encapsulation layer 117b can planarize an upper portion of the light emitting diode 120.

The first encapsulation layer 117a is disposed on the cathode 123 and is disposed to be most adjacent to the light emitting diode 120, in the encapsulation unit 117. For example, the first encapsulation layer 117a can be configured by silicon nitride (SiNx), silicon oxide (SiOx), silicon oxynitride (SiON), or aluminum oxide (Al₂O₃) but is not limited thereto.

The second encapsulation layer 117b can be formed to have a smaller area than that of the first encapsulation layer 117a. In this case, the second encapsulation layer 117b can be formed to expose both ends of the first encapsulation layer 117a. The second encapsulation layer 117b can serve to enhance a buffering function to alleviate stress between the layers due to bending of the flexible display device and a planarization function.

For example, the second encapsulation layer 117b can be formed of an organic insulating material, such as acrylic resin, epoxy resin, polyimide, polyethylene, or silicon oxy carbon (SiOC). For example, the second encapsulation layer 117b can be formed by an inkjet method, but is not limited thereto.

The third encapsulation layer 117c can be formed above the substrate 110 on which the second encapsulation layer 117b is formed so as to cover upper surfaces and side surfaces of the second encapsulation layer 117b and the first encapsulation layer 117a. At this time, the third encapsulation layer 117c can minimize or block the permeation of external moisture or oxygen into the first encapsulation layer 117a and the second encapsulation layer 117b. For example, the third encapsulation layer 117c can be configured by an inorganic insulating material, such as silicon nitride (SiNx), silicon oxide (SiOx), silicon oxynitride (SiON), or aluminum oxide (Al₂O₃), but can be limited thereto.

The touch sensing layer can be disposed on the encapsulation unit 117.

The touch sensing layer can include the touch buffer layer 118a, the touch interlayer insulating layer 118b, the touch electrode TE, and the touch planarization layer 118c. The touch electrode TE can include a touch sensor electrode TS and a touch bridge electrode TB located on different layers.

For example, the touch buffer layer 118a can be disposed above the third encapsulation layer 117c and the touch bridge electrode TB can be disposed on the touch buffer layer 118a.

The touch interlayer insulating layer 118b can be disposed on the touch bridge electrode TB and the touch sensor electrode TS can be disposed on the touch interlayer insulating layer 118b.

The touch planarization layer 118c is disposed on the touch sensor electrode TS. The touch planarization layer 118c can be an organic layer which planarizes and protects an upper portion of the touch sensor electrode TS. Therefore, the touch planarization layer 118c can be disposed to be in contact with the touch sensor electrode TS. For example, the touch planarization layer 118c can be formed of an organic material such as acryl resin, epoxy resin, phenolic resin, polyamide resin, or polyimide resin, but is not limited thereto. For example, the touch buffer layer 118a, the touch interlayer insulating layer 118b, and the touch planarization layer 118c can be formed of an inorganic insulating material or an organic insulating material. Therefore, the touch buffer layer 118a, the touch interlayer insulating layer 118b, and the touch planarization layer 118c can minimize a step in a location where the touch electrode TE is disposed and electrically insulate the touch sensor electrode TS and the touch bridge electrode TB.

The third planarization layer 119 is disposed on the touch planarization layer 118c. The third planarization layer 119 can planarize upper portions of the plurality of touch electrodes TE. Specifically, the third planarization layer 119 can be configured to entirely planarize upper portions of the display area AA, the first non-display area NA1, and the second non-display area NA2 on the substrate 110. Therefore, the third planarization layer 119 can be a configuration which is disposed on the uppermost layer in the display panel PN, but is not limited thereto. The third planarization layer 119 can be formed of an organic material, such as epoxy-based resin, but is not limited thereto.

The second adhesive layer AD2 and the polarizer POL to be described below can be disposed on the third planarization layer 119. The second adhesive layer AD2 is disposed to be in contact with a top surface of the third planarization layer 119 and a bottom surface of the polarizer POL to bond between the third planarization layer 119 and the polarizer POL, but is not limited thereto.

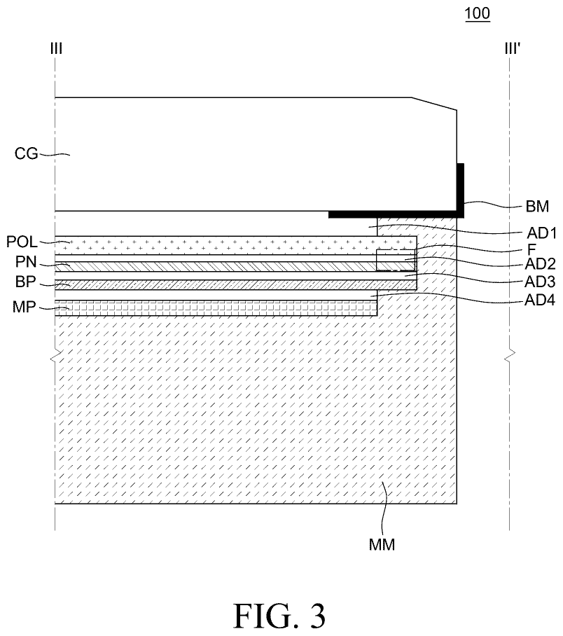

Hereinafter, a cross-sectional structure of the first non-display area NA1 of the display panel PN will be described with reference to FIG. 3 together.

FIG. 3 is a cross-sectional view of a display device 100 according to an example embodiment of the present disclosure. In FIG. 3, among various components of the display device 100, the display panel PN, a cover window CG, a back plate BP, a metal plate MP, and a molding member MM are illustrated.

Referring to FIG. 3, the display device 100 according to aspects of the present disclosure includes the display panel PN, the cover window CG, the back plate BP, the metal plate MP, and the molding member MM.

The cover window CG is disposed on a front surface of the display panel PN. The cover window CG can be a component which is exposed to the outer periphery of the display device 100 and protect the display device 100 from external shock or scratches. Further, the cover window CG can protect the display device 100 from moisture permeating from the outside. The cover window CG can be formed of a glass or a plastic material having a flexibility, but is not limited thereto.

A black matrix BM is disposed below the cover window CG. The black matrix BM can be disposed along the circumference of the cover window CG on the other periphery of the cover window CG. At this time, the area in which the black matrix BM is disposed can correspond to the first non-display area NA1. The black matrix BM can be formed of a material having a low permeability. Therefore, the black matrix BM can suppress various components disposed below the first non-display area NA1 from being visible to the outside. Further, the black matrix BM is formed of a material having a conductivity to discharge static electricity of the cover window CG.

The black matrix BM can be configured by chrome (Cr), graphite, or resin including conductive particles. Here, the resin can be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. Further, the conductive particle can also be formed of any one of molybdenum (Mo), chrome (Cr), titanium (Ti), nickel (Ni), neodymium (Nd), copper (Cu), and an alloy of silver (Ag) and magnesium (Mg), but is not limited thereto.

The polarizer POL is disposed between the display panel PN and the cover window CG. The polarizer POL can be disposed on the front surface of the display panel PN. The polarizer POL selectively transmits light to reduce the reflection of external light which is incident onto the display panel PN. Specifically, the display panel PN includes various metal materials applied to the semiconductor element, the wiring line, and the organic light emitting diode. Therefore, the external light incident onto the display panel PN can be reflected from the metal material so that the visibility of the display device 100 can be reduced due to the reflection of the external light. In contrast, when the polarizer POL is disposed, the polarizer POL suppresses the reflection of the external light so that the outdoor visibility of the display device 100 can be increased. However, the polarizer POL can be omitted depending on an implementation embodiment of the display device 100, but it is not limited thereto.

The first adhesive layer AD1 is disposed between the polarizer POL and the cover window CG and the second adhesive layer AD2 is disposed between the polarizer POL and the display panel PN. The first adhesive layer AD1 can bond the cover window CG and the polarizer POL and the second adhesive layer AD2 can bond the polarizer POL and the display panel PN. As a result, the first adhesive layer AD1 and the second adhesive layer AD2 can bond the display panel PN and the cover window CG. The first adhesive layer AD1 and the second adhesive layer AD2 can be formed as transparent adhesive layers so that an image of the display panel PN is visible. For example, the first adhesive layer AD1 and the second adhesive layer AD2 can be formed of optical clear adhesives, but are not limited thereto.

The back plate BP is disposed below the display panel PN. The back plate BP can be disposed so as to support the display panel PN. For example, when the substrate of the display panel PN is formed of a plastic material, such as polyimide, due to the flexible property, a separate component for protecting the substrate can be necessary. Therefore, a support substrate which is formed of glass is disposed below the substrate to perform a manufacturing process of the display device 100 and the support substrate can be separated to be released after completing the manufacturing process. However, a component for supporting the substrate is necessary even after releasing the support substrate, so that the back plate BP for supporting the substrate can be disposed below the display panel PN.

The back plate BP can include a plastic material. For example, the back plate BP can be formed of a plastic thin film formed of polyimide (PI), polyethylene naphthalate (PEN), polyethylene terephthalate (PET), or a combination of the polymers.

The third adhesive layer AD3 is disposed between the display panel PN and the back plate BP. The third adhesive layer AD3 can bond the display panel PN and the back plate BP. The third adhesive layer AD3 can be formed of a pressure sensitive adhesive (PSA), but is not limited thereto.

The metal plate MP is disposed below the back plate BP. The metal plate MP can protect the components of the display device 100 from external shocks. Further, the metal plate MP serves as a ground to suppress the static electricity entering the display device 100 or easily discharge residual charges accumulated in the display device 100 to the outside. Further, the metal plate MP can easily discharge heat generated in the display device 100 to the outside. The metal plate MP can be formed of a metal material having excellent thermal conductivity, electrical conductivity, and mechanical rigidity. For example, the metal plate MP can be configured by copper (Cu) or stainless steel (SUS), but is not limited thereto.

The fourth adhesive layer AD4 is disposed between the back plate BP and the metal plate MP. The fourth adhesive layer AD4 can bond the back plate BP and the metal plate MP to each other. The fourth adhesive layer AD4 can be formed of a pressure sensitive adhesive (PSA), but is not limited thereto.

The molding member MM seals the cover window CG, the display panel PN, the back plate BP, and the metal plate MP. Specifically, the molding member MM can be disposed so as to enclose a lower portion of the cover window CG, a side surface of the display panel PN, a side surface of the back plate BP, a side surface and a part of a bottom surface of the metal plate MP. The molding member MP can suppress the permeation of the moisture or oxygen into the display device 100. Further, the molding member MM can protect components of the display device 100 and relieve shocks applied to the display device 100.

For example, the molding member MM can be formed by a process of removing a mold, after filling and curing the mold which is disposed to surround a side surface of the cover window CG and expose a side surface of the display panel PN, a side surface of the back plate BP, a side surface and a part of a bottom surface of the metal plate MP with a material for forming the molding member MM. However, the method of forming the molding member MM is not limited thereto.

For example, the molding member MM can be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

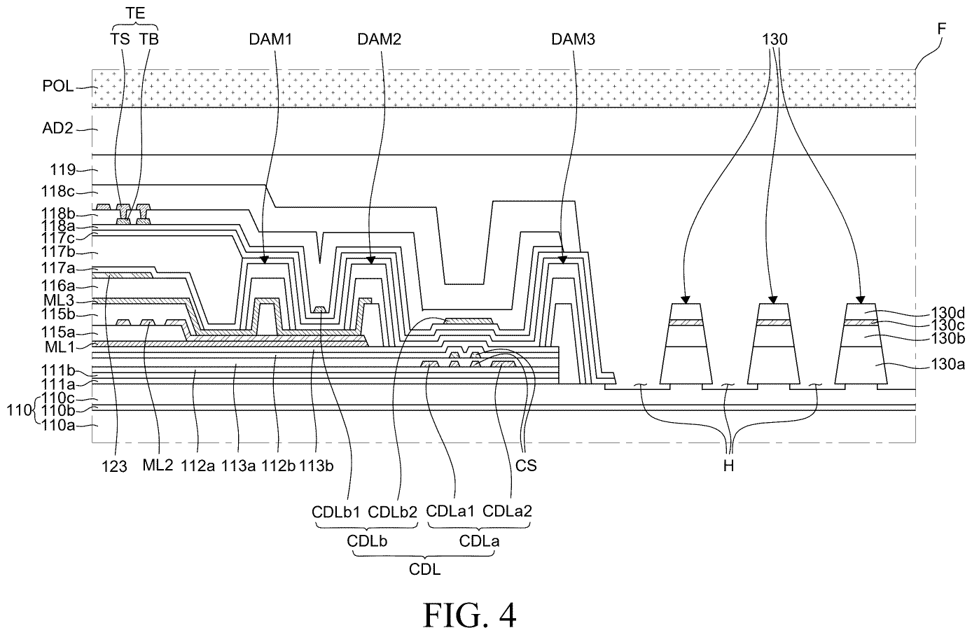

Hereinafter, a cross-sectional structure of the first non-display area NA1 of the display panel PN will be described in more detail with reference to FIG. 4 together.

FIG. 4 is an enlarged cross-sectional view of an area F of FIG. 3. Particularly, FIG. 4 is a cross-sectional view illustrating a cross-sectional structure of a first non-display area NA1 according to an example embodiment of the present disclosure.

Referring to FIG. 4, in the display device 100 according to the example embodiment of the present disclosure, in the first non-display area NA1 of the display panel PN, a first metal layer ML1, a second metal layer ML2, a third metal layer ML3, a plurality of crack detection lines CDL, a plurality of crack stoppers CS, a first dam DAM1, a second dam DAM2, a third dam DAM3, and a plurality of hanging units 130 are disposed.

In the first non-display area NA1, the first metal layer ML1 is disposed on the second interlayer insulating layer 113b. The first metal layer ML1 can be formed of the same material as one of various conductive components formed in the display area AA. For example, the first metal layer ML1 can be formed on the second interlayer insulating layer 113b by the same process and with the same material as the source electrodes S1 and S2 and the drain electrodes D1 and D2, but the present disclosure is not limited thereto.

For example, the first metal layer ML1 can be a low potential power line. The first metal layer ML1 can be electrically connected to the cathode 123 through the second metal layer ML2 and the third metal layer ML3. Therefore, the first metal layer ML1 can supply a low potential voltage to the cathode 123.

The second metal layer ML2 is disposed on the first metal layer ML1 and the first planarization layer 115a. The second metal layer ML2 can be disposed along a circumference of the substrate 110 at the outermost periphery of the first non-display area NA1. The second metal layer ML2 can be formed of the same material as one of various conductive components formed in the display area AA. For example, the second metal layer ML2 can be formed on the first planarization layer 115a by the same process and with the same material as the second connection electrode CE2, but the present disclosure is not limited thereto.

In the meantime, referring to FIG. 4, the second metal layer ML2 can include a plurality of holes. Therefore, gas which is generated from the first planarization layer 115a or the second planarization layer 115b during the manufacturing process can be easily discharged to the outside through the plurality of holes of the second metal layer ML2.

The third metal layer ML3 is disposed on the second metal layer ML2 and the second planarization layer 115b. The third metal layer ML3 extends onto the second metal layer ML2 to be in contact with the second metal layer ML2. The third metal layer ML3 can be formed of the same material as one of various conductive components formed in the display area AA. The third metal layer ML3 can be formed by the same process and with the same material as the anode 121, but the present disclosure is not limited thereto.

In the meantime, the third metal layer ML3 is electrically connected to the cathode 123 in the first non-display area NA1. Therefore, the third metal layer ML3 can supply a low power voltage which is supplied through the first metal layer ML1 and the second metal layer ML3 to the cathode 123.

In the first non-display area NA1, a plurality of dams is disposed in an area adjacent to an end of the substrate 110. Each of the plurality of dams is disposed so as to surround the display area AA in the first non-display area NA1.

The plurality of dams can include a first dam DAM1, a second dam DAM2, and a third dam DAM3.

The first dam DAM1 and the second dam DAM2 can be disposed so as to overlap the first metal layer ML1, the second metal layer ML2, and the third metal layer ML3, but are not limited thereto. The first dam DAM1 and the second dam DAM2 can be configured to be disposed to be adjacent to the display area AA to suppress excessive application of the second encapsulation layer 117b.

The third dam DAM3 can be an outermost dam disposed at the outermost periphery of the display panel PN, among the plurality of dams. The third dam DAM3 can cover ends of the plurality of inorganic insulating layers 111, 112a, 113a, 112b, and 113b disposed in the first non-display area NA1, but is not limited thereto.

The first dam DAM1, the second dam DAM2, and the third dam DAM3 can have a structure in which a plurality of organic layers formed of the same material as components disposed in the display area AA is laminated. For example, the first dam DAM1, the second dam DAM2, and the third dam DAM3 can be formed by the same process and with the same material as the second planarization layer 115b, the bank 116a, and the spacer 116b, respectively, but are not limited thereto.

Further, even though in FIG. 4, it is illustrated that the plurality of dams is configured by three dams, the first dam DAM1, the second dam DAM2, and the third dam DAM3, is not limited thereto and the number of the plurality of dams can vary if necessary.

In the first non-display area NA1, the plurality of crack detection lines CDL is disposed. The plurality of crack detection lines CDL can be disposed inside from the third dam DAM3 which is the outermost dam.

A lower detection line CDLa, among the plurality of crack detection lines CDL, can be formed of the same material as one of various conductive components formed in the display area AA. For example, the lower detection line CDLa can be formed on the first gate insulating layer 112a by the same process and with the same material as the first gate electrode G1. Therefore, the lower detection line CDLa can sense a crack generated on the layers adjacent to the lower detection line CDLa, such as the substrate 110, the first buffer layer 111, the first gate insulating layer 112a, the first interlayer insulating layer 113a, the second buffer layer 114, the second gate insulating layer 112b, and the second interlayer insulating layer 113b. However, the present disclosure is not limited thereto and the lower detection line CDLa can be formed by the same process as another conductive component, other than the first gate electrode G1.

The lower detection line CDLa can include a first lower detection line CDLa1 and a second lower detection line CDLa2. The first lower detection line CDLa1 and the second lower detection line CDLa2 are spaced apart from each other with a predetermined interval and can be disposed in parallel to each other. The first lower detection line CDLa1 can be disposed inside more than the second lower detection line CDLa2.

In the meantime, referring to FIG. 4, the plurality of crack stoppers CS is disposed between the first lower detection line CDLa1 and the second lower detection line CDLa2. The plurality of crack stoppers CS can be configured to increase lengths of the plurality of inorganic layers disposed in the first non-display area NA1 or disconnect the connection of the plurality of inorganic layers. Therefore, the plurality of crack stoppers CS can minimize propagation of crack to the display area AA through the plurality of inorganic layers in the first non-display area NA1.

For example, the plurality of crack stoppers CS can be formed by the same process and with the same material as the first gate electrode G1 or the second capacitor electrode C2, but is not limited thereto.

An upper detection line CDLb, among the plurality of crack detection lines CDL, can be formed of the same material as one of various conductive components formed in the display area AA. For example, the upper detection line CDLb can be formed on the touch buffer layer 118a by the same process and with the same material as the touch bridge electrode TB. Therefore, the upper detection line CDLb can sense cracks generated on the layers adjacent to the upper detection line CDLb, such as the encapsulation unit 117, the touch buffer layer 118a, and the touch interlayer insulating layer 118b. Further, the upper detection line CDLb can be a hole crack detection line which senses a crack generated in the hole when an opening, such as a camera hole is formed in the display area AA. However, the present disclosure is not limited thereto and the upper detection line CDLb can be formed by the same process as another conductive component, other than the encapsulation unit 117, the touch buffer layer 118a, and the touch interlayer insulating layer 118b.

The upper detection line CDLb can include a first upper detection line CDLb1 and a second upper detection line CDLb2. The first upper detection line CDLb1 and the second upper detection line CDLb2 are spaced apart from each other with a predetermined interval and can be disposed in parallel to each other. Referring to FIG. 4, the first upper detection line CDLb1 can be disposed inside more than the second upper detection line CDLb2. For example, the first upper detection line CDLb1 can be disposed between the first dam DAM1 and the second dam DAM2 and the second upper detection line CDLb2 can be disposed between the second dam DAM2 and the third dam DAM3, but are not limited thereto.

In the meantime, referring to FIG. 4, in the first non-display area NA1, the first encapsulation layer 117a and the third encapsulation layer 117c of the encapsulation unit 117 are disposed so as to cover the first dam DAM1, the second dam DAM2, and the third dam DAM3. Therefore, the ends of the first encapsulation layer 117a and the third encapsulation layer 117c can be disposed on the substrate 110.

The substrate 110 includes a plurality of grooves H between the third dam DAM3, which is the outermost dam, among the plurality of dams and the plurality of hanging units 130 and between the plurality of hanging units 130, at the outer periphery of the first non-display area NA1. At this time, the end portions of the first encapsulation layer 117a and the third encapsulation layer 117c can be exposed by the groove H of the substrate 110.

The touch planarization layer 118c is disposed on the plurality of touch electrodes TE and the plurality of dams DAM1, DAM2, and DAM3. The touch planarization layer 118c can extend to top surfaces of the plurality of dams DAM1, DAM2, and DAM3, above the plurality of touch electrodes TE.

The plurality of hanging units 130 is disposed on the substrate 110 at the outer periphery of the first non-display area NA1. The plurality of hanging units 130 can be configured to serve to increase the adhesiveness of the third planarization layer 119 and the substrate 110 disposed thereabove and perform a hanging function. Therefore, the plurality of hanging units 130 can minimize the separation of the interface of the third planarization layer 119 and the substrate 110 at the outer periphery of the first non-display area NA1.

The plurality of hanging units 130 includes a first layer 130a, a second layer 130b on the first layer 130a, a third layer 130c on the second layer 130b, and a fourth layer 130d on the third layer 130c.

The first layer 130a can be at least one inorganic layer which is formed of an inorganic material. For example, the first layer 130a can be formed of the same material as any one or more of the first buffer layer 111, the first gate insulating layer 112a, the first interlayer insulating layer 113a, the second buffer layer 114, the second gate insulating layer 112b, and the second interlayer insulating layer 113b, but is not limited thereto.

The second layer 130b can be an organic layer which is formed of an organic material. For example, the second layer 130b can be formed of the same material as the first planarization layer 115a, but is not limited thereto.

The third layer 130c can be a metal layer formed of metal. For example, the third layer 130c can be formed of the same material as the second connection electrode CE2, but is not limited thereto.

The fourth layer 130d can be an organic layer which is formed of an organic material. For example, the fourth layer 130d can be formed of the same material as the second planarization layer 115b, but is not limited thereto.

Widths of the first layer 130a, the second layer 130b, the third layer 130c, and the fourth layer 130d can be reduced upwardly. For example, the first layer 130a, the second layer 130b, the third layer 130c, and the fourth layer 130d can have a regular tapered shape. At this time, a part of bottom surfaces of the plurality of hanging units 130 can be exposed by the plurality of grooves H of the substrate 110. The plurality of hanging units 130 is disposed between the plurality of grooves H and bottom surfaces of the plurality of hanging units 130 are larger than the top surface of the substrate 110 between the plurality of grooves H so that the plurality of grooves H and the plurality of hanging units 130 can form an under-cut shape. For example, the plurality of grooves H extends below the plurality of hanging units 130 to form the under-cut shape.

The third planarization layer 119 is disposed on the touch planarization layer 118c.

The third planarization layer 119 can be configured to planarize an upper portion of the touch planarization layer 118c to entirely planarize upper portions of the display area AA and the first non-display area NA1 on the substrate 110. At this time, the third planarization layer 119 disposed on the plurality of hanging units 130 can be disposed to be filled between the substrate 110 and the plurality of hanging units 130. For example, the third planarization layer 119 can be filled between the plurality of dams Dam1, DAM2, and DAM3 and between the plurality of hanging units 130, in the first non-display area NA1. For example, the third planarization layer 119 can be disposed along an interface with the substrate 110 and the plurality of hanging units 130 while filling the under-cut. At this time, a part of the bottom surface of the first layer 130a is exposed by the plurality of grooves H of the substrate 110 to be in contact with the third planarization layer 119.

At this time, the third planarization layer 119 fills the plurality of grooves H of the substrate 110 disposed between the plurality of hanging units 130 to minimize the lifting phenomenon above the display panel PN by the plurality of hanging units 130 and also minimize separation of the interface with the substrate 110 after trimming.

In the display device, the molding member which integrally formed with the configuration of the display device while directly enclosing the component can be disposed below a side surface of the display panel and below the side surface of the cover window. Therefore, a separate configuration, such as a cover unit which protects the components of the display device, can be omitted due to the molding member so that it is advantageous to implement a narrow bezel.

However, in the display panel, a volume of the component formed of the organic material can be contracted or expand in a low temperature or a high temperature environment so that there can be a defect that the components formed of an organic material and the molding member are separated from each other.

Further, even though a component formed of an organic material is contracted, a material having an adhesion, such as an adhesive layer, may not be spaced apart from the molding member due to the adhesion. Therefore, on the bonding surface of the organic layer which is in contact with the adhesive layer, a stress is concentrated to cause a crack.

During a manufacturing process of the display device, a side surface of the display panel can be subject to a process of cutting a base substrate by a trimming process.

At this time, there can be a problem in that an interface of the planarization layer which is formed of an organic material which planarizes an uppermost portion of the display panel at the outermost periphery of the non-display area, with the substrate, is separated. For example, the trimming area at the outermost periphery of the non-display area has a structure in which the planarization layer which is the uppermost layer of the display panel abuts with the substrate which is the lowermost layer. In this structure, the adhesion between the planarization layer and the substrate is not good so that the interface of the planarization layer and the substrate after the trimming process is separated.

Further, when an external shock is generated, there can be a problem in that in the trimming area, the crack propagates to the display area due to the interface separation of the planarization layer and the substrate. For example, when the crack propagates to the display area through the organic layer, moisture can permeate the display panel through the cracked portion. Therefore, there is a serious problem of degradation of a display quality of the display device.

In the display device 100 according to the example embodiment of the present disclosure, the plurality of hanging units 130 is disposed at the outermost periphery of the display panel PN to minimize the interface separation of the third planarization layer 119 from the substrate 110.

Specifically, in the display device 100 according to the example embodiment of the present disclosure, the plurality of hanging units 130 is disposed on the substrate 110 at the outer periphery of the first non-display area NA1 and the third planarization layer 119 is disposed to cover the upper portion of the substrate 110 and the plurality of hanging units 130. At this time, the plurality of grooves H is disposed between the substrate 110 and the plurality of hanging units 130 and the third planarization layer 119 can fill the plurality of grooves H of the substrate 110 disposed between the plurality of hanging units 130. Therefore, the plurality of hanging units 130 can minimize the upward lifting of the display panel PN and minimize the separation of the interface with the substrate 110 after trimming. Accordingly, in the display device 100 according to the example embodiment of the present disclosure, the plurality of hanging units 130 is disposed at the outermost periphery of the display panel PN to minimize the interface separation of the third planarization layer 119 from the substrate 110 and improve the reliability of the display device 100. Further, the display device 100 can be configured to minimize the crack generated due to the interface separation of the third planarization layer 119 and the substrate 110 at the outer periphery of the non-display area NA from being transmitted to the display area AA and improve the display quality of the display device 100.

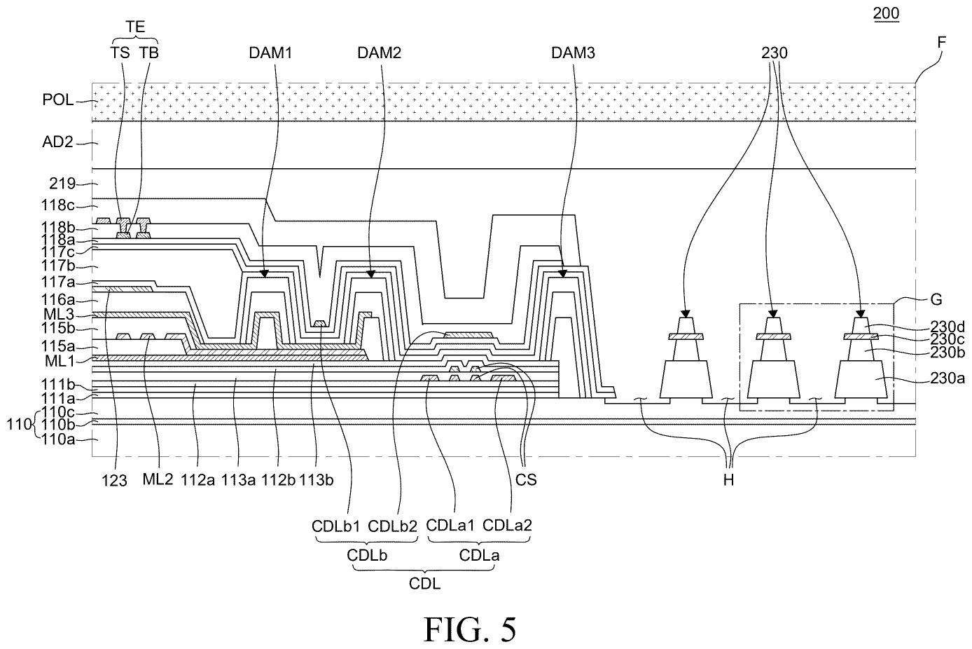

FIG. 5 is a cross-sectional view of a display device according to another example embodiment of the present disclosure. The only difference or a main difference between a display device 200 of FIG. 5 and the display device 100 of FIGS. 1 to 4 is a plurality of hanging units 230 and a third planarization layer 219, but the other configuration is the same, so that a redundant description will be omitted or briefly provided.

Referring to FIG. 5, the plurality of hanging units 230 is disposed on the substrate 110 at the outer periphery of the first non-display area NA1. The plurality of hanging units 230 can be configured to serve to increase the adhesiveness of the third planarization layer 219 and the substrate 110 disposed thereabove and perform a hanging function. Therefore, the plurality of hanging units 230 can minimize the separation of the interface of the third planarization layer 219 and the substrate 110 at the outer periphery of the first non-display area NA1.

The plurality of hanging units 230 includes a first layer 230a, a second layer 230b on the first layer 230a, a third layer 230c on the second layer 230b, and a fourth layer 230d on the third layer 230c.

The first layer 230a can be at least one inorganic layer which is formed of an inorganic material. For example, the first layer 230a can be formed of the same material as any one or more of the first buffer layer 111, the first gate insulating layer 112a, the first interlayer insulating layer 113a, the second buffer layer 114, the second gate insulating layer 112b, and the second interlayer insulating layer 113b, but is not limited thereto.

The second layer 230b can be an organic layer which is formed of an organic material. For example, the second layer 230b can be formed of the same material as the first planarization layer 115a, but is not limited thereto.

The third layer 230c can be a metal layer formed of metal. For example, the third layer 230c can be formed of the same material as the second connection electrode CE2.

The fourth layer 230d can be an organic layer which is formed of an organic material. For example, the fourth layer 230d can be formed of the same material as the second planarization layer 115b.

A width of the first layer 230a and a width of the third layer 230c can be larger than a width of the second layer 230b and a width of the fourth layer 230d. The width of the first layer 230a can be larger than the width of the third layer 230c and the width of the second layer 230b can be larger than the width of the fourth layer 230d. For example, the widths of the plurality of hanging units 230 are repeatedly increased and decreased toward the upper portion of the substrate 110 so that the side surfaces of the plurality of hanging units 230 can have a protruding shape on the cross-section. At this time, a part of a top surface of the first layer 230a and parts of a top surface and a bottom surface of the third layer 230c can be in contact with the third planarization layer 219. Therefore, the contact area of the plurality of hanging units 230 with the third planarization layer 219 can be larger.

The third planarization layer 219 can be configured to entirely planarize upper portions of the display area AA and the first non-display area NA1 on the substrate 110. At this time, the third planarization layer 219 disposed on the plurality of hanging units 230 can be disposed to fill between the substrate 110 and the plurality of hanging units 230. For example, the third planarization layer 219 can fill between the plurality of dams Dam1, DAM2, and DAM3 and between the plurality of hanging units 230, in the first non-display area NA1. For example, the third planarization layer 219 can fill the under-cut between the plurality of grooves H and the plurality of hanging units 230. At this time, a part of the bottom surface of the first layer 230a is exposed by the plurality of grooves H of the substrate 110 to be in contact with the third planarization layer 219. The third planarization layer 219 can be disposed along the protruding side surface of the plurality of hanging units 230 therebetween.

At this time, the third planarization layer 219 fills the plurality of grooves H of the substrate 110 disposed between the plurality of hanging units 230 and a concave portion formed by the protruding side surfaces of the plurality of hanging units 230. Therefore, it is possible to minimize the lifting phenomenon above the display panel PN by the plurality of hanging units 230 and also minimize separation of the interface with the substrate 110 after trimming.

Therefore, in the display device 200 according to another example embodiment of the present disclosure, the plurality of hanging units 230 is disposed at the outer periphery of the display panel PN to minimize the interface separation of the third planarization layer 219 from the substrate 110.

Specifically, in the display device 200 according to another example embodiment of the present disclosure, the plurality of hanging units 230 is disposed on the substrate 110 at the outer periphery of the first non-display area NA1 and the third planarization layer 219 is disposed to cover the substrate 110 and the plurality of hanging units 230. At this time, a plurality of grooves H is disposed between the substrate 110 and the plurality of hanging units 230. Further, the plurality of hanging units 230 is configured such that a width of the first layer 230a and a width of the third layer 230c are larger than a width of the second layer 230b and a width of the fourth layer 230d to have a protruding side surface. The third planarization layer 219 fills the plurality of grooves H of the substrate 110 disposed between the plurality of hanging units 230 and can be disposed along the protruding side surface of the plurality of hanging units 230. Therefore, the plurality of hanging units 230 can minimize the lifting phenomenon above the display panel PN and minimize the separation of the interface with the substrate 110 after trimming. Accordingly, in the display device 200 according to another example embodiment of the present disclosure, the plurality of hanging units 230 is disposed at the outermost periphery of the display panel PN to minimize the interface separation of the third planarization layer 219 from the substrate 110 and improve the reliability of the display device 200. Further, the display device 200 can be configured to minimize the crack generated due to the interface separation of the third planarization layer 219 and the substrate 110 at the outer periphery of the non-display area NA from being transmitted to the display area AA and improve the display quality of the display device 200.

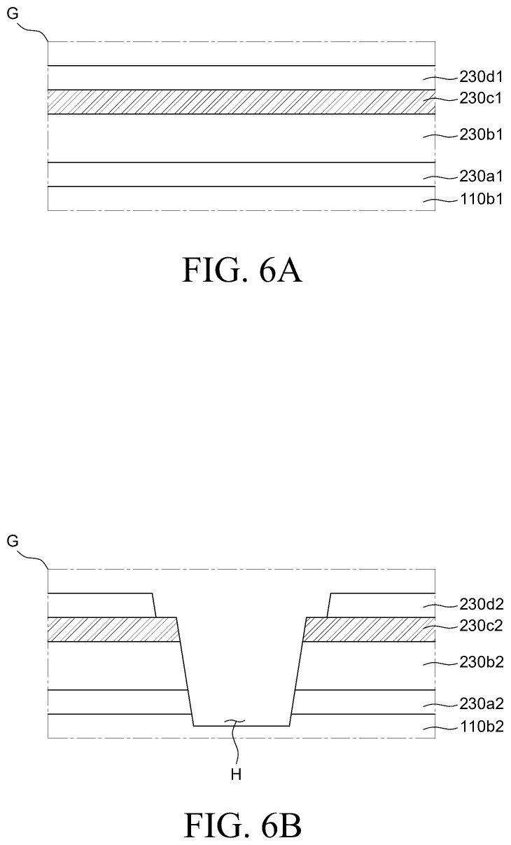

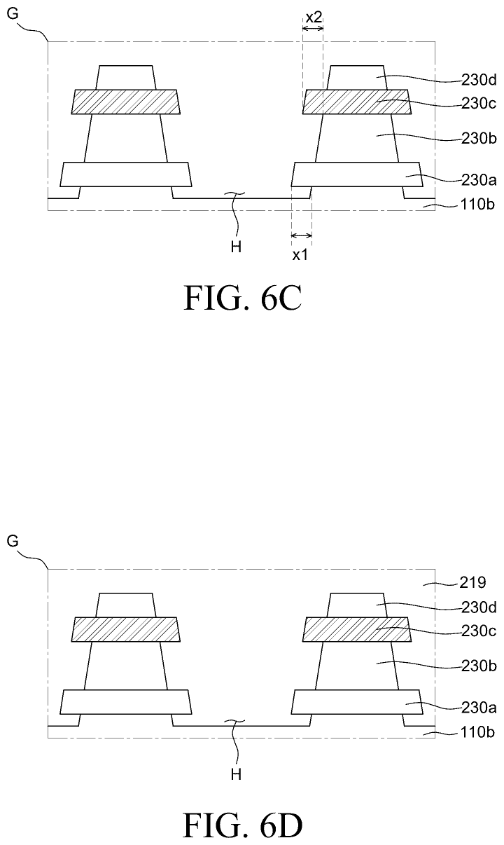

FIGS. 6A to 6D are process diagrams for explaining a manufacturing method of a display device according to another example embodiment of the present disclosure. Particularly, FIGS. 6A to 6D are process diagrams for explaining a forming process of a plurality of hanging units 230 in an area G of FIG. 5.

Referring to FIG. 6A, at least one inorganic layer 230a1, a first organic layer 230b1, a metal layer 230c1, and a second organic layer 230d1 are sequentially laminated on a substrate layer 110b1.

At this time, at least one inorganic layer 230a1 is one or more inorganic layers formed of an inorganic material and can be formed of the same material as any one or more of the first buffer layer 111, the first gate insulating layer 112a, the first interlayer insulating layer 113a, the second buffer layer 114, the second gate insulating layer 112b, and the second interlayer insulating layer 113b.

The first organic layer 230b1 is an organic layer formed of an organic material and can be formed of the same material as the first planarization layer 115a.

The metal layer 230c1 is a metal layer formed of metal and can be formed of the same material as the second connection electrode CE2.

The second organic layer 230d1 is an organic layer formed of an organic material and can be formed of the same material as the second planarization layer 115b.

Referring to FIG. 6B, the first organic layer 230b1, the metal layer 230c1, and the second organic layer 230d1 are patterned using a photo mask to form holes in the first organic layer 230b2, the metal layer 230c2, and the second organic layer 230d2 according to a predetermined interval. The substrate layer 110b1 and at least one inorganic layer 230a1 are patterned by an etching process to form holes in the substrate layer 110b2 and at least one inorganic layer 230a2 according to a predetermined interval. At this time, the predetermined interval of each of at least one inorganic layer 230a2, the first organic layer 230b2, the metal layer 230c2, and the second organic layer 230d2 can vary according to a process condition.

Referring to FIG. 6C, a groove H can be formed on the substrate 110b by an ashing process. The first layer 230a is disposed between the grooves H and a bottom surface of the first layer 230a is larger than a top surface of the substrate 110b of the groove H so that the groove H and the first layer 230a can form an under-cut shape.

Further, parts of the first organic layer 230b2 and the second organic layer 230d2 which are exposed to the outside can be removed by the ashing process. In the meantime, as long as the organic material is removed by the process of removing parts of the first organic layer 230b2 and the second organic layer 230d2, the process is not limited thereto.

Therefore, the first layer 230a which is exposed through a part of the bottom surface, the second layer 230b which has a width smaller than that of the first layer 230a, the third layer 230c which has a width larger than the width of the second layer 230b, and the fourth layer 230d which has a width smaller than the third layer 230c can be formed. At this time, a width ΔX1 of an exposed bottom surface of the first layer 230a and a width Δx2 of an exposed bottom surface of the third layer 230c can be the same.

Referring to FIG. 6D, the third planarization layer 219 can be applied above the plurality of hanging units 230 including the substrate 110b and the first layer 230a, the second layer 230b which has a width smaller than that of the first layer 230a, the third layer 230c which has a width larger than that of the second layer 230b, and the fourth layer 230d which has a width smaller than that of the third layer 230c. Therefore, the contact area between the third planarization layer 219 and the substrate 110b and the third planarization layer 219 and the plurality of hanging units 230 can be increased. Further, the width ΔX1 of an exposed bottom surface of the first layer 230a and the width Δx2 of an exposed bottom surface of the third layer 230c of the plurality of hanging units 230 serve as a hanging unit which suppresses the lifting of the third planarization layer 219 above the substrate 110b. Therefore, the separation of the interface of the third planarization layer 219 from the substrate 110b after trimming process can be minimized.

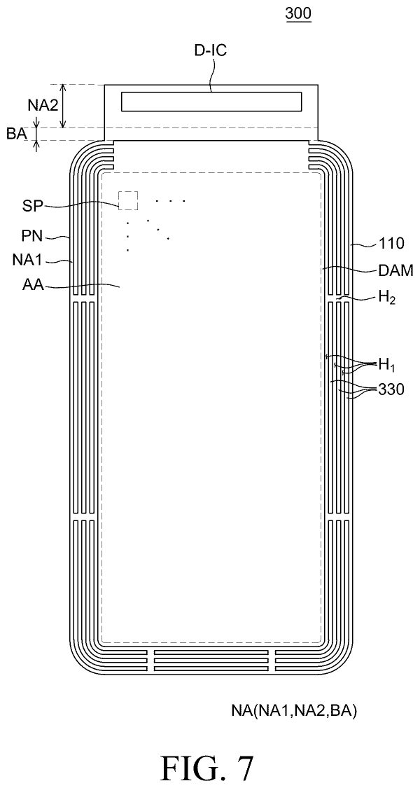

FIG. 7 is a schematic plan view of a display device according to still another example embodiment of the present disclosure. The only difference or a main difference between a display device 300 of FIG. 7 and the display device 100 of FIG. 1 is a plurality of hanging units 330, but the other configuration is substantially the same, so that a redundant description will be omitted or briefly provided.

Referring to FIG. 7, the plurality of hanging units 330 is disposed on the substrate 110 at the outer periphery of the first non-display area NA1. The plurality of hanging units 330 can be disposed so as to surround the dam DAM. The plurality of hanging units 330 can be disposed to be close to a trimming line. For example, the plurality of hanging units 330 can be disposed along trimming lines at a left side, a right side, and a lower side of the display panel PN.

At this time, the plurality of hanging units 330 can have a linear island shape along an outline of the display panel PN. For example, the plurality of hanging units 330 is disposed so as to surround the dam DAM, but is spaced apart from each other by the plurality of grooves H1 and H2 on the plane. Here, the plurality of grooves H1 and H2 can include a first groove H1 and a second groove H2. The first groove H1 is disposed between the dam DAM and the plurality of hanging units 330 and between long portions of the plurality of hanging units 330, at the outer periphery of the first non-display area NA1. The second groove H2 is disposed between short portions of the plurality of hanging units 330.

The plurality of hanging units 330 can be configured to increase adhesion of an organic layer disposed above the substrate 110 and the substrate 110 and perform a hanging function. At this time, the plurality of hanging units 330 has a larger contact area which serves to be hung between the organic layer disposed above the substrate 110 and the substrate 110 to maximize the hanging function. Further, even though any one linear hanging unit, among the plurality of hanging units 330 is damaged, the other hanging units can sufficiently perform a hanging function, other than the damaged hanging unit so that the interface separation of the organic layer and the substrate 110 can be minimized.

In the meantime, even though in FIG. 7, it is illustrated that three hanging units 330 are disposed at the left side and the right side of the dam DAM, respectively, a bezel size of the display panel PN can be adjusted according to the number of the plurality of hanging units 330 so that the present disclosure is not limited thereto.

Further, even though in FIG. 7, six second grooves H2 are provided between the plurality of hanging units 330, the second groove H2 on the substrate 110 can adjust the number of the plurality of hanging units 330 having a linear island shape, so that the present disclosure is not limited thereto.

In the meantime, the plurality of hanging units 330 is disconnected from the inorganic layer which is disposed so as to cover the dam DAM, by the plurality of grooves H1 and H2, so that the crack of the inorganic layer which can propagate to the substrate 110 can be minimized.

The example embodiments of the present disclosure can also be described as follows:

According to an aspect of the present disclosure, a display device includes a substrate including a display area and a non-display area surrounding the display area, a plurality of dams on the substrate so as to surround the display area in the non-display area, a plurality of hanging units on the substrate at an outer periphery of the non-display area and located further than the plurality of dams, and a planarization layer in the display area and the non-display area and filling between the plurality of dams and between the plurality of hanging units in the non-display area.

The substrate can include a plurality of grooves between an outermost dam, among the plurality of dams, and the plurality of hanging units and between the plurality of hanging units.

The plurality of grooves can extend below the plurality of hanging units so that bottom surfaces of the plurality of hanging units are exposed by the grooves.

The plurality of grooves and the plurality of hanging units can form an under-cut shape.

The plurality of hanging units can includes at least one first layer on the substrate and formed of an inorganic material, a second layer on the first layer and formed of an organic material, a third layer on the second layer and formed of metal and a fourth layer on the third layer and formed of an organic material.

Widths of the first layer, the second layer, the third layer, and the fourth layer can be upwardly decreased.

A width of the first layer and a width of the third layer can be larger than a width of the second layer and a width of the fourth layer.

The width of the first layer can be larger than the width of the third layer and the width of the second layer can be larger than the width of the fourth layer.

The display device can further include at least oneinorganic insulating layer on the substrate in the display area, a plurality of transistors on the substrate in the display area, a first planarization layer on the at least one inorganic insulating layer and the plurality of transistors, a plurality of connection electrodes on the first planarization layer and electrically connected to each of the plurality of transistors, a second planarization layer on the first planarization layer and the plurality of connection electrodes and a plurality of light emitting diodes on the second planarization layer and is electrically connected to the plurality of connection electrodes, respectively. The first layer can be formed of the same material as the inorganic insulating layer, the second layer can be formed of the same material as the first planarization layer, the third layer can be formed of the same material as the plurality of connection electrodes and the fourth layer can be formed of the same material as the second planarization layer.

The display device can further include a plurality of light emitting diodes on the substrate in the display area, an encapsulation unit on the plurality of light emitting diodes in the display area and covering the plurality of dams in the non-display area and a touch sensing layer on the encapsulation unit in the display area. The planarization layer can be disposed on the touch sensing layer in the display area.

According to another aspect of the present disclosure, a display device includes a substrate including a display area and a non-display area surrounding the display area, a plurality of hanging units on the substrate at an outer periphery of the non-display area, and a planarization layer in the display area and the non-display area. The substrate includes a plurality of grooves between the plurality of hanging units and the planarization layer fills the plurality of grooves in the non-display area.

The plurality of grooves can extend below the plurality of hanging units so that bottom surfaces of the plurality of hanging units are exposed by the grooves.

The plurality of grooves and the plurality of hanging units can form an under-cut shape.

The plurality of hanging units can includes at least one first layer on the substrate and formed of an inorganic material, a second layer on the first layer and formed of an organic material, a third layer on the second layer and formed of metal and a fourth layer on the third layer and formed of an organic material.

Widths of the first layer, the second layer, the third layer, and the fourth layer can be upwardly decreased.

A width of the first layer and a width of the third layer can be larger than a width of the second layer and a width of the fourth layer.

The width of the first layer can be larger than the width of the third layer and the width of the second layer can be larger than the width of the fourth layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a display area and a non-display area adjacent to the display area;
a plurality of dams disposed in the non-display area of the substrate and surrounding at least a part of the display area;
a plurality of hanging units disposed at an outer periphery of the non-display area, and positioned further than the plurality of dams; and
a planarization layer in the display area and the non-display area, and filling areas between the plurality of dams and between the plurality of hanging units in the non-display area.

2. The display device according to claim 1, wherein the substrate includes a plurality of grooves between an outermost dam among the plurality of dams and the plurality of hanging units and between the plurality of hanging units.

3. The display device according to claim 2, wherein the plurality of grooves extends below the plurality of hanging units so that bottom surfaces of the plurality of hanging units are exposed by the plurality of grooves.

4. The display device according to claim 2, wherein the plurality of grooves and the plurality of hanging units form an under-cut shape.

5. The display device according to claim 2, wherein the plurality of hanging units includes:
at least one first layer on the substrate and including an inorganic material;
a second layer on the at least one first layer and including an organic material;
a third layer on the second layer and including metal; and
a fourth layer on the third layer and including an organic material.

6. The display device according to claim 5, wherein widths of the at least one first layer, the second layer, the third layer, and the fourth layer are upwardly decreased.

7. The display device according to claim 5, wherein a width of the at least one first layer and a width of the third layer are larger than a width of the second layer and a width of the fourth layer.

8. The display device according to claim 7, wherein the width of the at least one first layer is larger than the width of the third layer, and the width of the second layer is larger than the width of the fourth layer.

9. The display device according to claim 5, further comprising:
at least one inorganic insulating layer on the substrate in the display area;
a plurality of transistors on the substrate in the display area;
a first planarization layer on the at least one inorganic insulating layer and the plurality of transistors;
a plurality of connection electrodes on the first planarization layer and electrically connected to each of the plurality of transistors;
a second planarization layer on the first planarization layer and the plurality of connection electrodes; and
a plurality of light emitting diodes on the second planarization layer and electrically connected to the plurality of connection electrodes, respectively,
wherein the at least one first layer is formed of a same material as the at least one inorganic insulating layer, the second layer is formed of a same material as the first planarization layer, the third layer is formed of a same material as the plurality of connection electrodes and the fourth layer is formed of a same material as the second planarization layer.

10. The display device according to claim 1, further comprising:
a plurality of light emitting diodes on the substrate in the display area;
an encapsulation unit on the plurality of light emitting diodes in the display area and covering the plurality of dams in the non-display area; and
a touch sensing layer on the encapsulation unit in the display area,
wherein the planarization layer is disposed on the touch sensing layer in the display area.

11. The display device according to claim 1, wherein the plurality of hanging units is disposed to be parallel to the plurality of dams on a plane and has a linear shape.

12. The display device according to claim 1, wherein the plurality of hanging units is disposed to be parallel to the plurality of dams on a plane and has a linear island shape.

13. A display device comprising:
a substrate including a display area and a non-display area adjacent to the display area;
a plurality of hanging units on the substrate at an outer periphery of the non-display area; and
a planarization layer in the display area and the non-display area,
wherein the substrate includes a plurality of grooves disposed between the plurality of hanging units, and the planarization layer fills the plurality of grooves in the non-display area.

14. The display device according to claim 13, wherein the plurality of grooves extends below the plurality of hanging units so that bottom surfaces of the plurality of hanging units are exposed by the plurality of grooves.

15. The display device according to claim 13, wherein the plurality of grooves and the plurality of hanging units form an under-cut shape.

16. The display device according to claim 13, wherein the plurality of hanging units includes:
at least one first layer on the substrate and including an inorganic material;
a second layer on the at least one first layer and including an organic material;
a third layer on the second layer and including metal; and
a fourth layer on the third layer and including an organic material.

17. The display device according to claim 16, wherein widths of the at least one first layer, the second layer, the third layer, and the fourth layer are upwardly decreased.

18. The display device according to claim 16, wherein a width of the at least one first layer and a width of the third layer are larger than a width of the second layer and a width of the fourth layer.

19. The display device according to claim 18, wherein the width of the at least one first layer is larger than the width of the third layer, and the width of the second layer is larger than the width of the fourth layer.

20. The display device according to claim 13, wherein the plurality of hanging units has a linear shape on a plane or a linear island shape.
